(19) United States
(12) Patent Application Publication
(10) Pub. No.: US 2014/0255829 A1
(43) Pub. Date: Sep. 11, 2014

(54) MASK FOR DUAL TONE DEVELOPMENT

(71) Applicant: Powerchip Technology Corporation, Hsinchu (TW)

(72) Inventors: Yi-Shiang Chang, Changhua County (TW); Chia-Chi Lin, Hsinchu County (TW); Hung-Ming Lin, Hsinchu County (TW)

(73) Assignee: Powerchip Technology Corporation, Hsinchu (TW)

(21) Appl. No.: 13/896,334

(22) Filed: May 17, 2013

(30) Foreign Application Priority Data
Mar. 7, 2013 (TW) 102108055

(51) Int. Cl. G03F 1/50

(52) U.S. Cl. CPC G03F 1/50
USPC 430/5

(57) ABSTRACT

A mask for dual tone development including a opening pattern region and a partial transparent pattern is provided. The opening pattern region includes a plurality of transparent patterns and a plurality of opaque patterns, and a plurality of opening patterns is defined in a photoresist for dual tone development by the transparent patterns and the opaque patterns. The partial transparent pattern surrounds the opening pattern region.

### CROSS-REFERENCE TO RELATED APPLICATION

This application claims the priority benefit of Taiwan application serial no. 102108055, filed on Mar. 7, 2013. The entirety of the above-mentioned patent application is hereby incorporated by reference herein and made a part of this specification.

### BACKGROUND OF THE INVENTION

1. Field of the Invention

The invention relates to a mask, and more particularly to a mask for dual tone development.

2. Description of Related Art

In the semiconductor integrated circuit process, the photolithography process is one of the most critical steps. The photolithography process includes performing a photoresist coating step, an exposure step and a development step, and so on. First, in the photolithography process, a photoresist layer is spin coated on a working surface of a wafer. In the exposure process, due to the photoresist layer is photosensitive, the photoresist layer may be patterned by radiation light through a mask. In the development process, the wafer may be placed in a washing liquid which is known as a developer, so that the non-polymerizable portion in the photoresist is dissolved in the developer to obtain a patterned photoresist layer. The patterned photoresist layer on the working surface of the wafer irradiated with the radiation light may be used as a pattern or a template used in subsequent process steps of the integrated circuit.

In general, a mask is composed of a transparent pattern and a opaque pattern. The mask is designed to avoid the radiation light passing through the specific portion of the photoresist layer, so that the photoresist irradiated with the radiation light in the specific range thereof may subject to polymerization or non-polymerization.

FIG. 1 is a schematic view illustrating a conventional monotone development.

Referring to FIG. 1, when a pattern of a mask 10 is transferred to a photoresist 20 by performing a photolithography process, the photoresist 20 first is exposed by using the mask 10, and then a positive tone development is performed to the exposed photoresist 20, whereby a portion of the photoresist 20 corresponding to a maximum light field is removed. At this time, a pitch Pa of openings 12 in the mask 10 is about equal to a pitch Pb of openings 22 in the photoresist 20.

FIG. 2 is a schematic view illustrating a conventional dual tone development.

Referring to FIG. 2, when a pattern of a mask 30 is transferred to a photoresist 40 by performing a photolithography process, the photoresist 40 first is exposed by using the mask 30, and then a dual tone development composed of a positive tone development and a negative tone development is performed to the exposed photoresist 40, whereby a portion of the photoresist 40 corresponding to a maximum light field and a minimum light field is removed. At this time, a pitch Pc of openings 32 in the mask 30 is about twice to a pitch Pd of openings 42 in the photoresist 40.

### SUMMARY OF THE INVENTION

The invention is provided to a mask for dual tone development that may significantly reduce the manufacturing cost of the semiconductor device.

The invention is directed a mask for dual tone development that includes an opening pattern region and a partial transparent pattern. The opening pattern region includes a plurality of transparent patterns and a plurality of opaque patterns, and a plurality of opening patterns is defined in a photoresist for dual tone development by the transparent patterns and the opaque patterns. The partial transparent pattern surrounds the opening pattern region.

According to an embodiment of the invention, in the mask for dual tone development, the transparent patterns are, for instance, arranged in a 2-dimension array, and the opaque patterns are, for instance, arranged in a mesh pattern and surround each of the transparent patterns.

According to an embodiment of the invention, in the mask for dual tone development, the opaque patterns are, for instance, arranged in a 2-dimension array, and the transparent patterns are, for instance, arranged in a mesh pattern and surround each of the opaque patterns.

According to an embodiment of the invention, the mask for dual tone development further includes a guard ring pattern that at least surrounds a portion of the partial transparent pattern.

According to an embodiment of the invention, in the mask for dual tone development, the guard ring pattern is transparent or opaque, for instance.

According to an embodiment of the invention, in the mask for dual tone development, a pitch of the opening patterns of the photoresist for dual tone development is 50% to 75% of a pitch of the transparent patterns of the mask for dual tone development, for instance.

According to an embodiment of the invention, in the mask for dual tone development, a pitch of the opening patterns of the photoresist for dual tone development is 50% to 75% of a pitch of the opaque patterns of the mask for dual tone development, for instance.

According to an embodiment of the invention, in the mask for dual tone development, the transparent patterns and the opaque patterns are alternately arranged in a 1-dimension array without intervals, for instance.

According to an embodiment of the invention, in the mask for dual tone development, a ratio of a width of each of the transparent patterns to a width of each of the opaque patterns is 1:1 to 7:1, for instance.

According to an embodiment of the invention, in the mask for dual tone development, a ratio of a width of each of the transparent patterns to a width of each of the opaque patterns is 1:1 to 1:7, for instance.

According to an embodiment of the invention, in the mask for dual tone development, a pitch of the opening patterns of the photoresist for dual tone development is 50% to 75% of a pitch of the opaque patterns of the mask for dual tone development, for instance.

According to an embodiment of the invention, in the mask for dual tone development, a pitch of the opening patterns of the photoresist for dual tone development is 50% to 75% of a pitch of the transparent patterns of the mask for dual tone development, for instance.

According to an embodiment of the invention, the mask for dual tone development further comprises an isolation region opening pattern located in an isolation region.

According to an embodiment of the invention, in the mask for dual tone development, the partial transparent pattern is a grating or a partial transparent material, for instance.

According to an embodiment of the invention, in the mask for dual tone development, the opening patterns are contact hole patterns, for instance.

According to an embodiment of the invention, in the mask for dual tone development, when the transparent patterns and the opaque patterns are arranged in at least one row, the transparent patterns and the opaque patterns located on the same row are, for instance, alternately arranged and spaced apart by a certain distance, and the partial transparent pattern is contained between each of the transparent patterns and each of the opaque patterns adjacent to each other.

According to an embodiment of the invention, in the mask for dual tone development, the transparent patterns and the opaque patterns located on the different rows are alternately arranged or aligned with each other, for instance.

According to an embodiment of the invention, in the mask for dual tone development, when the transparent patterns and the opaque patterns located on the different rows are aligned with each other, the transparent patterns located on the different rows are aligned with each other, the opaque patterns located on the different rows are aligned with each other, or the transparent patterns located on one row and the opaque patterns located on another row are aligned with each other.

In view of the above, the mask for dual tone development disclosed in an embodiment of the invention includes the partial transparent pattern, so the patterned photoresist for dual tone development which includes both the opening pattern region and the photoresist pattern surrounding the opening pattern region may be formed by a single mask and a single exposure process. Therefore, by using the mask for dual tone development of the invention, the manufacturing cost of the semiconductor device may be significantly reduced, and the complexity of the semiconductor process may be effectively simplified.

In addition, by using the mask for dual tone development disclosed in an embodiment of the invention, the opening patterns with smaller pitch may be formed in the photoresist for dual tone development.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view illustrating a conventional monotone development.

FIG. 2 is a schematic view illustrating a conventional dual tone development.

FIG. 3 is a schematic view illustrating a mask for dual tone development according to an embodiment of the invention.

FIG. 4 is a schematic view illustrating a patterned photoresist for dual tone development formed by using the mask for dual tone development of FIG. 3.

FIG. 5 is a schematic view illustrating a mask for dual tone development according to another embodiment of the invention.

FIG. 6 is a schematic view illustrating a patterned photoresist for dual tone development formed by using the mask for dual tone development of FIG. 5.

FIG. 7 is a schematic view illustrating a mask for dual tone development according to another embodiment of the invention.

FIG. 8 is a schematic view illustrating a patterned photoresist for dual tone development formed by using the mask for dual tone development of FIG. 7.

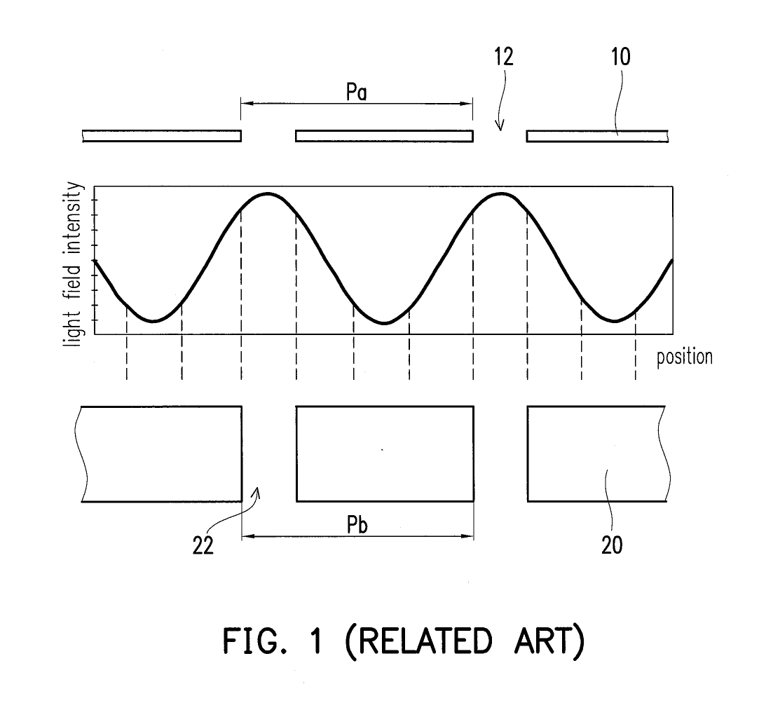

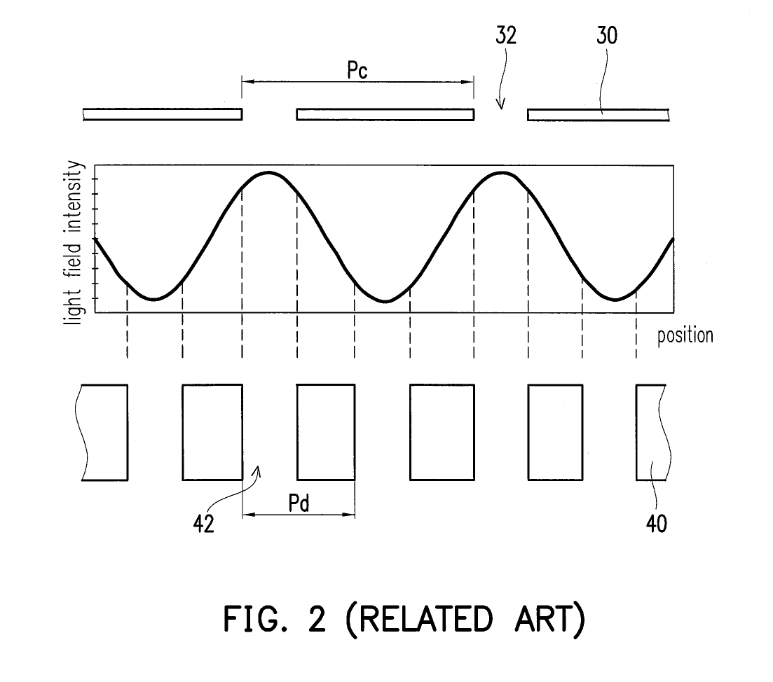

### DESCRIPTION OF EMBODIMENTS

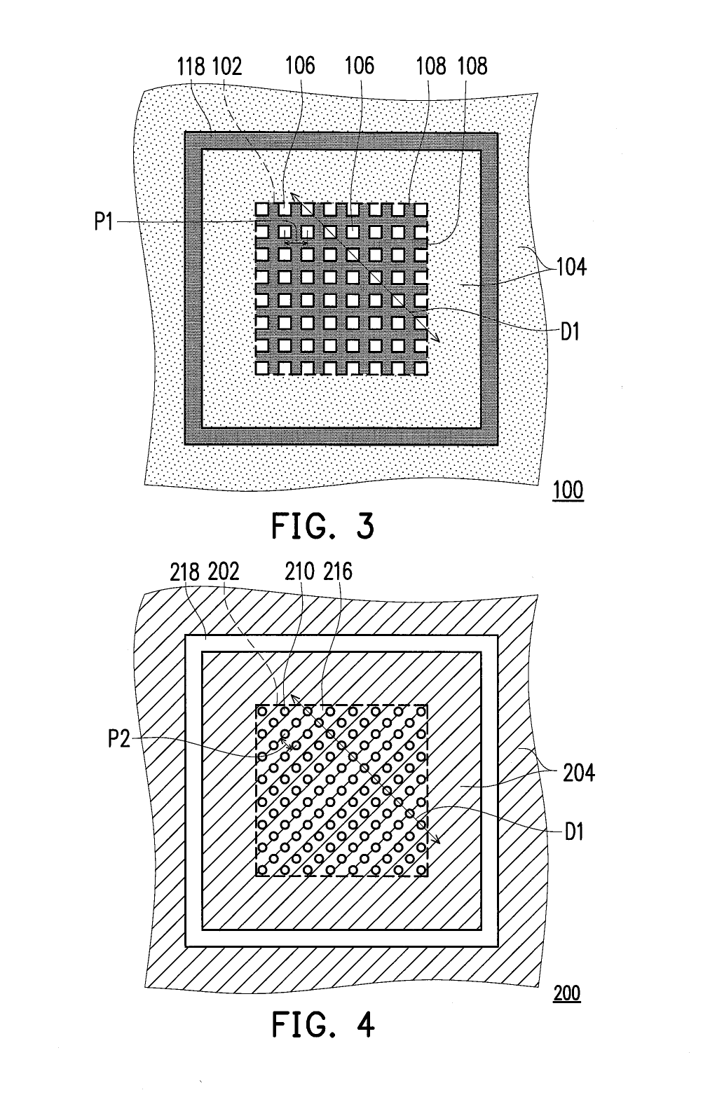

FIG. 3 is a schematic view illustrating a mask for dual tone development according to an embodiment of the invention. FIG. 4 is a schematic view illustrating a patterned photoresist for dual tone development formed by using the mask for dual tone development of FIG. 3.

Referring to FIG. 3, a mask for dual tone development 100 includes a opening pattern region 102 and a partial transparent pattern 104.

The opening pattern region 102 includes a plurality of transparent patterns 106 and opaque patterns 108, and in subsequent exposure and development processes, a plurality of opening patterns 210 (with reference to FIG. 4) may be defined in a photoresist for dual tone development by the transparent patterns 106 and the opaque patterns 108. The opening patterns 210 are, for instance, contact hole patterns, such as contact hole patterns of a dynamic random access memory. When a exposure process is performed by using the mask for dual tone development 100, a maximum light field is formed at the transparent patterns 106 because radiation light can pass through the transparent patterns 106; a minimum light field is formed at the opaque patterns 108 because the radiation light is shielded by the opaque patterns 108; and a medium light field between the maximum light field and the minimum light field is formed at the edge of the transparent patterns 106 and at the edge of the opaque patterns 108. The material of the opaque patterns 108 is chromium, for instance. The opening pattern region 102 is a dense region, for instance.

In the present embodiment, the transparent patterns 106 are, for instance, arranged in a 2-dimension array, and the opaque patterns 108 are, for instance, cross to each other and arranged in a mesh pattern, wherein the transparent patterns 106 are spaced apart by a pitch P1 and the transparent patterns 106 are respectively surrounded by the opaque patterns 108. In the present embodiment, although the shape of the transparent patterns 106 are rectangle and the shape of the opaque patterns 108 are strip, people having ordinary skill in the pertinent art may adjust the shape of the transparent patterns 106 and the opaque patterns 108 according to the actual design requirements. In another embodiment, the opaque patterns may also be arranged in a 2-dimension array, and the transparent patterns may also be arranged in a mesh pattern and surround the opaque patterns so as to achieve the same function as that of the above-described embodiment.

The partial transparent pattern 104 surrounds the opening pattern region 102. The property of the partial transparent pattern 104 is that the radiation light only can partially pass through the partial transparent pattern 104 so as to form the medium light field between the maximum light field and the minimum light field. The partial transparent pattern 104 is, for instance, a grating or a partial transparent material, wherein the partial transparent material is, for instance, molybdenum silicide (MoSi).

In addition, the mask for dual tone development 100 may selectively include a guard ring pattern 118. The guard ring pattern 118 at least surrounds the opening pattern region 102 and a portion of the partial transparent pattern 104. The guard ring pattern 118 is transparent or opaque, for instance. In the present embodiment, the guard ring pattern 118 described herein is opaque, for instance.

Referring to FIG. 3 and FIG. 4 simultaneously, in the photolithography process performed by using the mask for dual tone development 100, after a exposure process and a dual tone development process are performed on the photoresist for dual tone development, a patterned photoresist for dual tone development 200 may form. The material of the photoresist for dual tone development is a photo acid generator (PAG), resin or propylene glycol monomethyl ether acetate (PGMEA), for instance.

In the dual tone development process, the photoresist for dual tone development receiving the maximum light field and the minimum light field may be removed, and the rest of the photoresist for dual tone development may be retained. In the present embodiment, in the exposure process, the maximum light field (e.g. light field intensity more than about 0.16) which corresponds to the transparent patterns 106 and the minimum light field (e.g. light field intensity less than about 0.05) which corresponds to the opaque patterns 108 are arranged along a diagonal direction D1 of the opening pattern region 102. Therefore, after the dual tone development process, the plurality of opening patterns 210 arranged along the diagonal direction D1 are formed in the photoresist for dual tone development corresponding to the opening pattern region 102. Furthermore, the pitch P2 of the opening patterns 210 are less than the pitch P1 of the transparent patterns 106, and the pitch P2 is, for instance, 50% to 75% of the pitch P1.

In another embodiment, when the opaque patterns are arranged in a 2-dimension array, and the transparent patterns are arranged in a mesh pattern and surround the opaque patterns, the pitch of the opening patterns of the photoresist for dual tone development is, for instance, 50% to 75% of the pitch of the opaque patterns of the mask for dual tone development.

In the exposure process, the partial transparent pattern 104 will not form the maximum light field or the minimum light field, and thus after the dual tone development process, the photoresist for dual tone development corresponding to the partial transparent pattern 104 will all be retained.

In addition, the patterned photoresist for dual tone development 200 may selectively include a guard ring pattern 218, and the guard ring pattern 218 are formed corresponding to the guard ring pattern 118.

In view of the above-described embodiment, after the exposure process and the dual tone development process, the photoresist for dual tone development corresponding to the partial transparent pattern 104 will be retained, and thus the plurality of opening patterns 210 may be formed in the photoresist for dual tone development and a portion of the photoresist for dual tone development surrounding the opening patterns 210 may be retained by using the mask for dual tone development 100. Because the patterned photoresist for dual tone development 200 may be formed by using a single mask and a single photolithography process, the manufacturing cost of the semiconductor device may be significantly reduced and the complexity of the semiconductor process may be effectively simplified by using the mask for dual tone development 100.

In addition, Because the opening pattern region 102 in the mask for dual tone development 100 is defined by the transparent patterns 106 and the opaque patterns 108, the opening patterns 210 in the patterned photoresist for dual tone development 200 formed by using the mask for dual tone development 100 may have the smaller pitch P2.

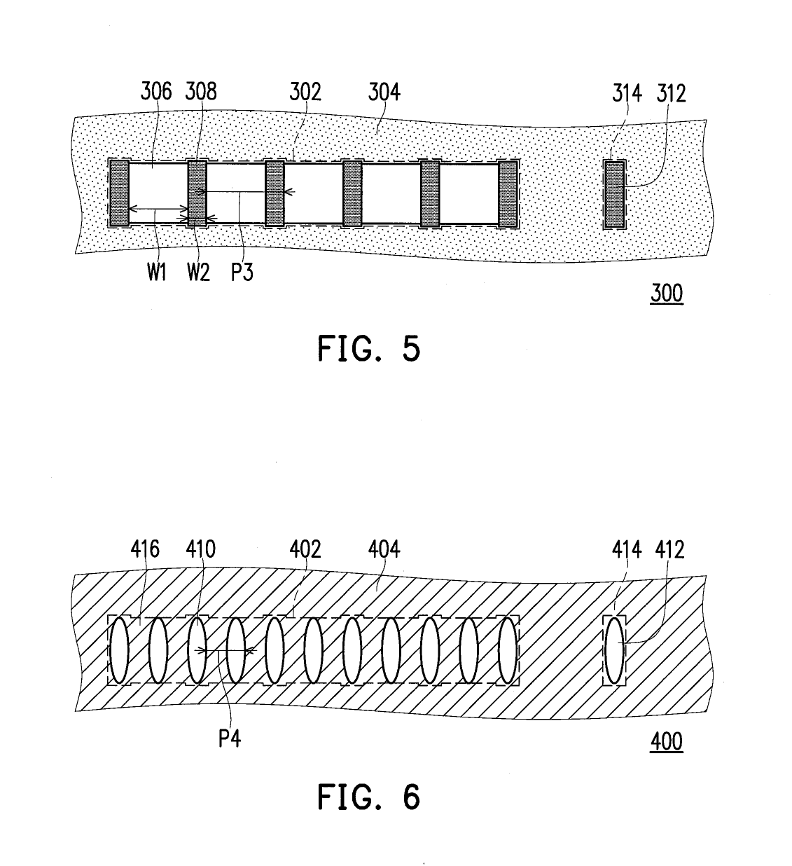

FIG. 5 is a schematic view illustrating a mask for dual tone development according to another embodiment of the invention. FIG. 6 is a schematic view illustrating a patterned photoresist for dual tone development formed by using the mask for dual tone development of FIG. 5.

Referring to FIG. 5, a mask for dual tone development 300 includes a opening pattern region 302 and a partial transparent pattern 304.

The opening pattern region 302 includes transparent patterns 306 and opaque patterns 308. When a exposure process is performed by using the mask for dual tone development 300, a maximum light field is formed at the transparent patterns 306 because the radiation light can pass through the transparent patterns 306; a minimum light field is formed at the opaque patterns 308 because the radiation light is shielded by the opaque patterns 308; and a medium light field between the maximum light field and the minimum light field is formed at the edge of the transparent patterns 306 and at the edge of the opaque patterns 308. The material of the opaque patterns 308 is chromium, for instance. The opening pattern region 302 is a dense region, for instance.

In the present embodiment, the transparent patterns 306 and the opaque patterns 308 are, for instance, alternately arranged in a 1-dimension array without intervals. The width W1 of the transparent patterns 306 is more than the width W2 of the opaque patterns 308, for instance. The ratio of the width W1 of the transparent patterns 306 to the width W2 of the opaque patterns 308 is 1:1 to 7:1, for instance. In the present embodiment, although the shape of the transparent patterns 306 and the opaque patterns 308 are rectangle, people having ordinary skill in the pertinent art may adjust the shape of the transparent patterns 306 and the opaque patterns 308 according to the actual design requirements. In another embodiment, the width of the transparent patterns may also be less than the width of the opaque patterns so as to achieve the same function as that of the above-described embodiment. In this case, the ratio of the width of the transparent patterns to the width of the opaque patterns is 1:1 to 1:7, for instance.

The partial transparent pattern 304 surrounds the opening pattern region 302. The property of the partial transparent pattern 304 is that the radiation light only can partially pass through the partial transparent pattern 304 so as to form the medium light field between the maximum light field and the minimum light field. The partial transparent pattern 304 is, for instance, a grating or a partial transparent material, wherein the partial transparent material is, for instance, molybdenum silicide (MoSi).

In addition, the mask for dual tone development 300 may selectively include an isolation region opening pattern 312 located in an isolation region 314. The isolation region opening pattern 312 is transparent or opaque, for instance. In the present embodiment, the isolation region opening pattern 312 described herein is opaque, for instance.

Referring to FIG. 5 and FIG. 6 simultaneously, in the photolithography process performed by using the mask for dual tone development 300, after a exposure process and a dual tone development process are performed on the photoresist for dual tone development, a patterned photoresist for dual tone development 400 may form. The material of the photoresist for dual tone development is a photo acid generator (PAG), resin or propylene glycol monomethyl ether acetate (PGMEA), for instance.

In the dual tone development process, the photoresist for dual tone development corresponding to the maximum light field and the minimum light field may be removed, and the rest of the photoresist for dual tone development may be retained. In the present embodiment, the maximum light field and the minimum light field of the opening pattern region 302 are respectively located at the central part of the transparent patterns 306 and the central part of the opaque patterns 308. Furthermore, the opening patterns 410 will be formed in the photoresist for dual tone development corresponding to the maximum light field and the minimum light field, so that the pitch P4 of the opening patterns 410 are less than the pitch P3 of the opaque patterns 308, and the pitch P4 is, for instance, 50% to 75% of the pitch P3. The opening patterns 410 are, for instance, contact hole patterns, such as contact hole patterns of a flash memory.

In another embodiment, when the width of the transparent patterns is less than the width of the opaque patterns, e.g. the ratio of the width of the transparent patterns to the width of the opaque patterns is 1:1 to 1:7, the pitch of the opening patterns of the photoresist for dual tone development is, for instance, 50% to 75% of the pitch of the transparent patterns of the mask for dual tone development.

In addition, the photoresist for dual tone development which is between each of the opening patterns 410 and corresponds to the partial transparent pattern 304 will all be retained. This is because, in the exposure process, the above-mentioned positions in the photoresist for dual tone development do not receive the maximum light field or the minimum light field, after the dual tone development process the above-mentioned positions in the photoresist for dual tone development will not be removed.

Furthermore, the patterned photoresist for dual tone development 400 may selectively include an isolation region opening pattern 412. The isolation region opening pattern 412 is formed in an isolation region 414 corresponding to the isolation region opening pattern 312.

In view of the above-described embodiment, after the exposure process and the dual tone development process, the photoresist for dual tone development corresponding to the partial transparent pattern 304 will be retained, and thus the opening patterns 410 may be formed and the photoresist for dual tone development surrounding each of the opening patterns 410 may be retained at the same time by using the mask for dual tone development 300. Because the patterned photoresist for dual tone development 400 may be formed by using a single mask and a single photolithography process, the manufacturing cost of the semiconductor device may be significantly reduced and the complexity of the semiconductor process may be effectively simplified by using the mask for dual tone development 300.

In addition, because the opening patterns 410 of the patterned photoresist for dual tone development 400 are defined by the transparent patterns 306 and the opaque patterns 308 of the mask for dual tone development 300, the opening patterns 410 may have the smaller pitch P4.

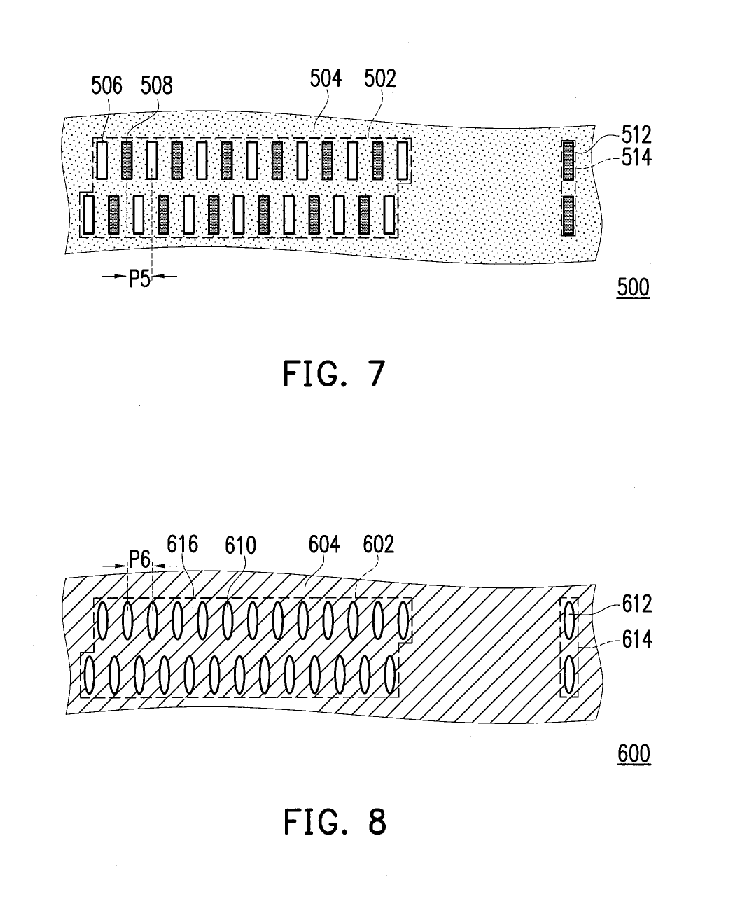

FIG. 7 is a schematic view illustrating a mask for dual tone development according to another embodiment of the invention. FIG. 8 is a schematic view illustrating a patterned photoresist for dual tone development formed by using the mask for dual tone development of FIG. 7.

Referring to FIG. 7, a mask for dual tone development 500 includes a opening pattern region 502 and a partial transparent pattern 504.

The opening pattern region 502 includes transparent patterns 506 and opaque patterns 508, and opening patterns 610 (as shown in FIG. 8) are defined by the transparent patterns 506 and the opaque patterns 508. When a exposure process is performed by using the mask for dual tone development 500, a maximum light field is formed at the transparent patterns 506 because the radiation light can pass through the transparent patterns 506; and a minimum light field is formed at the opaque patterns 508 because the radiation light is shielded by the opaque patterns 508. The material of the opaque patterns 508 is chromium, for instance. The opening pattern region 502 is a dense region, for instance. The opening patterns 610 are, for instance, contact hole patterns, such as contact hole patterns of a flash memory.

In the present embodiment, the opening patterns 610 are arranged in at least one row, for instance. In the present embodiment, the opening patterns 610 described herein are arranged in two rows, for instance, which should however not be construed as a limitation to the invention. As long as the arrangement of the opening patterns 610 is arranged as at least one row, the arrangement of the opening patterns 610 falls within the scope of the invention. In addition, the transparent patterns 506 and the opaque patterns 508 are, for instance, arranged in at least one row; the transparent patterns 506 and the opaque patterns 508 located on the same row are, for instance, alternately arranged and spaced apart by a certain distance; and the partial transparent pattern 504 is contained between each of the transparent patterns 506 and each of the opaque patterns 508 adjacent to each other. The size of the transparent patterns 506 is, for instance, the same as the size of the opaque patterns 508. In the present embodiment, although the shape of the transparent patterns 506 and the opaque patterns 508 are rectangle, people having ordinary skill in the pertinent art may adjust the shape of the transparent patterns 506 and the opaque patterns 508 according to the actual design requirements.

The partial transparent pattern 504 surrounds the opening pattern region 502. Furthermore, the partial transparent pattern 504 is also disposed in the opening pattern region 502 to isolate the transparent patterns 506 from the opaque patterns 508. The property of the partial transparent pattern 504 is that the radiation light only can partially pass through the partial transparent pattern 504 so as to form the medium light field between the maximum light field and the minimum light field. The partial transparent pattern 504 is, for instance, a grating or a partial transparent material, wherein the partial transparent material is, for instance, molybdenum silicide (MoSi).

On the other hand, the transparent patterns 506 and the opaque patterns 508 located on the different rows may be alternately arranged or aligned with each other. In the present embodiment, the transparent patterns 506 and the opaque patterns 508 located on the different rows which are described herein are alternately arranged, for instance. However, when the transparent patterns 506 and the opaque patterns 508 located on the different rows are aligned with each other, the alignment includes the transparent patterns 506 located on the different rows are aligned with each other, the opaque patterns 508 located on the different rows are aligned with each other, or the transparent patterns 506 located on one row and the opaque patterns 508 located on another row are aligned with each other. That is, people having ordinary skill in the pertinent art may adjust the arrangement of the transparent patterns 506 and the opaque patterns 508 located on the different rows according to the actual design requirements of products.

In addition, the mask for dual tone development 500 may selectively include an isolation region opening pattern 512 located in an isolation region 514. The isolation region opening pattern 512 is transparent or opaque, for instance. In the present embodiment, the isolation region opening pattern 512 described herein is opaque, for instance.

Referring to FIG. 7 and FIG. 8 simultaneously, in the photolithography process performed by using the mask for dual tone development 500, after a exposure process and a dual tone development process are performed on the photoresist for dual tone development, a patterned photoresist for dual tone development 600 may form. The material of the photoresist for dual tone development is a photo acid generator (PAG), resin or propylene glycol monomethyl ether acetate (PGMEA), for instance. The patterned photoresist for dual tone development 600 includes a opening pattern region 602.

The opening pattern region 602 of the patterned photoresist for dual tone development 600 is formed corresponding to the opening pattern region 502 of the mask for dual tone development 500. The opening pattern region 602 includes the plurality of opening patterns 610 separately arranged at intervals in the two adjacent rows, and the pitch P6 of the opening patterns 610 is, for instance, equal to the pitch P5 between the transparent patterns 506 and the opaque patterns 508. The reason is that in the dual tone development process, the photoresist for dual tone development corresponding to the transparent patterns 506 (the maximum light field) and the opaque patterns 508 (the minimum light field) will all be removed, and the photoresist for dual tone development corresponding to the partial transparent pattern 504 will be retained, and thus the pitch P6 of the opening patterns 610 is about equal to the pitch P5 between the transparent patterns 506 and the opaque patterns 508.

Furthermore, the patterned photoresist for dual tone development 600 may selectively include an isolation region opening pattern 612. The isolation region opening pattern 612 is formed in an isolation region 614 corresponding to the isolation region opening pattern 512.

Because the patterned photoresist for dual tone development 600 may be formed by using a single mask and a single photolithography process, the manufacturing cost of the semiconductor device may be significantly reduced and the complexity of the semiconductor process may be effectively simplified by using the mask for dual tone development 500.

To sum up, the mask for dual tone development described in the previous embodiments at least has the following properties. In the mask for dual tone development provided by the above-described embodiments, by a single mask and a single exposure process, the patterned photoresist for dual tone development which includes both the opening pattern region and the photoresist pattern surrounding the opening pattern region may be formed after the dual tone development process. In addition, the mask for dual tone development provided by the above-described embodiments may significantly reduce the manufacturing cost of the semiconductor device and effectively simplify the complexity of the semiconductor process. Furthermore, by using the mask for dual tone development provided by the above-described embodiments, the opening patterns with smaller pitch may be formed in the photoresist for dual tone development.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A mask for dual tone development, comprising:
a opening pattern region, comprising a plurality of transparent patterns and a plurality of opaque patterns, wherein a plurality of opening patterns is defined in a photoresist for dual tone development by the transparent patterns and the opaque patterns; and
a partial transparent pattern, surrounding the opening pattern region.

2. The mask for dual tone development as recited in claim 1, wherein the transparent patterns are arranged in a 2-dimension array, and the opaque patterns are arranged in a mesh pattern and surround each of the transparent patterns.

3. The mask for dual tone development as recited in claim 1, wherein the opaque patterns are arranged in a 2-dimension array, and the transparent patterns are arranged in a mesh pattern and surround each of the opaque patterns.

4. The mask for dual tone development as recited in claim 1, further comprising a guard ring pattern, at least surrounding a portion of the partial transparent pattern.

5. The mask for dual tone development as recited in claim 4, wherein the guard ring pattern is transparent or opaque.

6. The mask for dual tone development as recited in claim 2, wherein a pitch of the opening patterns of the photoresist for dual tone development is 50% to 75% of a pitch of the transparent patterns of the mask for dual tone development.

7. The mask for dual tone development as recited in claim 3, wherein a pitch of the opening patterns of the photoresist for dual tone development is 50% to 75% of a pitch of the opaque patterns of the mask for dual tone development.

8. The mask for dual tone development as recited in claim 1, wherein the transparent patterns and the opaque patterns are alternately arranged in a 1-dimension array without intervals.

9. The mask for dual tone development as recited in claim 8, wherein a ratio of a width of each of the transparent patterns to a width of each of the opaque patterns is 1:1 to 7:1.

10. The mask for dual tone development as recited in claim 8, wherein a ratio of a width of each of the transparent patterns to a width of each of the opaque patterns is 1:1 to 1:7.

11. The mask for dual tone development as recited in claim 9, wherein a pitch of the opening patterns of the photoresist for dual tone development is 50% to 75% of a pitch of the opaque patterns of the mask for dual tone development.

12. The mask for dual tone development as recited in claim 10, wherein a pitch of the opening patterns of the photoresist for dual tone development is 50% to 75% of a pitch of the transparent patterns of the mask for dual tone development.

13. The mask for dual tone development as recited in claim 8, further comprising an isolation region opening pattern, located in an isolation region.

14. The mask for dual tone development as recited in claim 1, wherein the partial transparent pattern comprises a grating or a partial transparent material.

15. The mask for dual tone development as recited in claim 1, wherein the opening patterns comprise contact hole patterns.

16. The mask for dual tone development as recited in claim 1, wherein when the transparent patterns and the opaque patterns are arranged in at least one row, the transparent patterns and the opaque patterns located on the same row are alternately arranged and spaced apart by a certain distance, and the partial transparent pattern is contained between each of the transparent patterns and each of the opaque patterns adjacent to each other.

17. The mask for dual tone development as recited in claim 16, wherein the transparent patterns and the opaque patterns located on the different rows are alternately arranged or aligned with each other.

18. The mask for dual tone development as recited in claim 17, wherein when the transparent patterns and the opaque patterns located on the different rows are aligned with each other, the transparent patterns located on the different rows are aligned with each other, the opaque patterns located on the different rows are aligned with each other, or the transparent patterns located on one row and the opaque patterns located on another row are aligned with each other.
